(19) United States
(12) Patent Application Publication
(10) Pub. No.: US 2026/0068268 A1
(43) Pub. Date: Mar. 5, 2026

(54) SEMICONDUCTOR DEVICES

(71) Applicant: Samsung Electronics Co., Ltd., Suwon-si (KR)

(72) Inventors: SUNG WAN LIM, Suwon-si (KR); HEON JONG SHIN, Suwon-si (KR); SEO WOO NAM, Suwon-si (KR); SUN WOO KIM, Suwon-si (KR); JUNE YOUNG PARK, Suwon-si (KR); HYE YOUNG PARK, Suwon-si (KR); DO WON SONG, Suwon-si (KR); SOO HEE SHIN, Suwon-si (KR); JUN KYU JUNG, Suwon-si (KR); SUNG GYU HAN, Suwon-si (KR)

(21) Appl. No.: 19/188,746

(22) Filed: Apr. 24, 2025

(30) Foreign Application Priority Data
Aug. 28, 2024 (KR) 10-2024-0116231

(51) Int. Cl. H10D 64/23; H10D 30/00; H10D 30/01

(52) U.S. Cl. CPC H10D 64/254; H10D 30/0198; H10D 30/501

(57) ABSTRACT

A semiconductor device includes a support substrate; a bonding layer on the support substrate; a first frontside wiring structure on the bonding layer; a second frontside wiring structure on the bonding layer, wherein the second frontside wiring structure is spaced apart from the first frontside wiring structure in a first direction; a frontside wiring pattern on the first frontside wiring structure and the second frontside wiring structure, wherein the frontside wiring pattern extends in the first direction; a frontside source/drain contact on the frontside wiring pattern; a source/drain pattern on the frontside source/drain contact; a backside wiring pattern on the source/drain pattern; a backside wiring structure on the backside wiring pattern; and a first via extending into the bonding layer, wherein the first via is in contact with the second frontside wiring structure, wherein the first via overlaps the second frontside wiring structure in a second direction.

### CROSS-REFERENCE TO RELATED APPLICATIONS

This application claims priority from Korean Patent Application No. 10-2024-0116231 filed on Aug. 28, 2024 in the Korean Intellectual Property Office, and all the benefits accruing therefrom under 35 U.S. C. 119, the contents of which in its entirety are herein incorporated by reference.

### BACKGROUND OF THE INVENTION

The present disclosure relates to semiconductor devices.

As one of the scaling technologies to increase the density of semiconductor devices, multi-gate transistors have been proposed, where a fin or nanowire-shaped multi-channel active pattern (or silicon body) is formed on a substrate and then gates are formed on the surface of a multi-channel active pattern.

Since these multi-gate transistors utilize three-dimensional (3D) channels, scaling may be easier (easier than a non-3D channel structure). Moreover, current control capabilities can be enhanced without increasing the gate length of the multi-gate transistors. Additionally, a short channel effect (SCE), where the potential of a channel region is influenced by a drain voltage, can be (effectively) suppressed.

Meanwhile, as the pitch size of semiconductor devices decreases, there is a need for research to ensure reduced capacitance between contacts, improved heat dissipation, and enhanced electrical stability within the semiconductor devices.

### SUMMARY OF THE INVENTION

Aspects of the present disclosure may provide semiconductor devices with improved performance and reliability.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to some embodiments of the present disclosure, there is provided a semiconductor device comprising a support substrate; a bonding layer on the support substrate; a first frontside wiring structure on the bonding layer; a second frontside wiring structure on the bonding layer, wherein the second frontside wiring structure is spaced apart from the first frontside wiring structure in a first direction that is parallel with an upper surface of the support substrate; a frontside wiring pattern on the first frontside wiring structure and the second frontside wiring structure, wherein the frontside wiring pattern extends in the first direction; a frontside source/drain contact on the frontside wiring pattern; a source/drain pattern on the frontside source/drain contact; a backside wiring pattern on the source/drain pattern; a backside wiring structure on the backside wiring pattern; and a first via extending into the bonding layer, wherein the first via is in contact with the second frontside wiring structure, wherein the first via overlaps the second frontside wiring structure in a second direction that is perpendicular to the upper surface of the support substrate.

According to some embodiments of the present disclosure, there is provided a semiconductor device comprising a support substrate; a bonding layer on the support substrate; a frontside wiring pattern on the bonding layer, wherein the frontside wiring pattern extends in a first direction that is parallel with an upper surface of the support substrate; a frontside wiring structure between the frontside wiring pattern and the bonding layer in a second direction that is perpendicular to the upper surface of the support substrate, wherein the frontside wiring structure is in contact with the frontside wiring pattern; a first via extends into the bonding layer and the support substrate, wherein the first via is in contact with the frontside wiring structure; a frontside source/drain contact on the frontside wiring pattern; a source/drain pattern on the frontside source/drain contact; a backside wiring pattern on the source/drain pattern, wherein the backside wiring pattern is spaced apart from the frontside wiring pattern in the second direction; a backside wiring structure on the backside wiring pattern; and a second via that is spaced apart from the backside wiring pattern in the first direction, wherein the second via extends in the second direction and connects the backside wiring pattern and the frontside wiring pattern, and wherein a lower surface of the second via is coplanar with a lower surface of the backside wiring pattern.

According to some embodiments of the present disclosure, there is provided a semiconductor device comprising a support substrate; a bonding layer on the support substrate; a first via extending into the support substrate and the bonding layer; a first frontside wiring structure on the bonding layer; a second frontside wiring structure on the first via, wherein the second frontside wiring structure is spaced apart from the first frontside wiring structure in a first direction that is parallel with an upper surface of the support substrate and in contact with the first via; a frontside wiring pattern on the first frontside wiring structure and the second frontside wiring structure, wherein the frontside wiring pattern extends in the first direction; a frontside source/drain contact on the frontside wiring pattern; a source/drain pattern on the frontside source/drain contact; a backside wiring pattern on the source/drain pattern; a backside wiring structure on the backside wiring pattern, wherein the backside wiring structure is in contact with the backside wiring pattern; a bump on the backside wiring structure; and a second via that is spaced apart from the backside wiring pattern in the first direction, wherein the second via extends in a second direction that is perpendicular to the upper surface of the support substrate between the frontside wiring pattern and the backside wiring structure, wherein the first via and the second via are free of overlap with the first frontside wiring structure in the second direction and overlap the second frontside wiring structure in the second direction, and wherein a lower surface of the second via is coplanar with a lower surface of the backside wiring pattern.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail example embodiments thereof with reference to the attached drawings, in which:

FIG. 1 is an example layout diagram for explaining a semiconductor device according to some embodiments of the present disclosure.

FIG. 2 is a cross-sectional view taken along A-A′ of FIG. 1.

FIG. 3 is a cross-sectional view taken along B-B′ of FIG. 1.

FIG. 4 is a cross-sectional view taken along C-C′ of FIG. 1.

FIG. 5 is an enlarged cross-sectional view of part P of FIG. 2.

FIG. 6 and FIG. 7 are diagrams for explaining a semiconductor device according to some embodiments of the present disclosure.

FIGS. 8 and 9 are diagrams for explaining semiconductor devices according to some embodiments of the present disclosure.

FIG. 10 is a diagram for explaining a semiconductor device according to some embodiments of the present disclosure.

FIGS. 11 through 16 are diagrams for explaining a method of manufacturing a semiconductor device according to some embodiments of the present disclosure.

### DETAILED DESCRIPTION

In this specification, although terms such as “first,” “second,” “upper,” and “lower” are used to describe various elements or components, these elements or components are not limited by these terms. These terms are merely used to distinguish one element or component from another. Therefore, a first element or component mentioned below may be a second element or component within the technical scope of the present disclosure. Similarly, a lower element or component mentioned below may be an upper element or component within the technical scope of the present disclosure. Herein, the terms indicating order, such as first, second, etc., are used to distinguish elements having the same/similar functions, and the ordinal numbers may be interchanged according to the order in which the terms are mentioned. To clarify the present disclosure, parts that are not connected with the description will be omitted, and the same elements or equivalents are referred to by the same reference numerals throughout the specification.

Embodiments of the present disclosure will hereinafter be described in detail with reference to the attached drawings. The same reference numerals are used for the same elements in the drawings unless clearly stated otherwise, and redundant descriptions thereof may be omitted.

In the accompanying drawings related to semiconductor devices according to some embodiments of the present disclosure, various types of transistors are exemplified, including transistors containing nanowires or nanosheets or Multi-Bridge Channel Field Effect Transistors (MBCFETs™), but the present disclosure is not limited thereto. The semiconductor devices according to some embodiments of the present disclosure may also be applicable to Fin Field-Effect Transistors (FinFETs) with fin-shaped patterned channel areas.

The semiconductor devices according to some embodiments of the present disclosure may include tunneling Field-Effect Transistors (FETs) or three-dimensional (3D) transistors, or vertical FETs, and may also include planar transistors. Additionally, the technical concept of the present disclosure can be applied to transistors based on two-dimensional (2D) materials and their heterostructures.

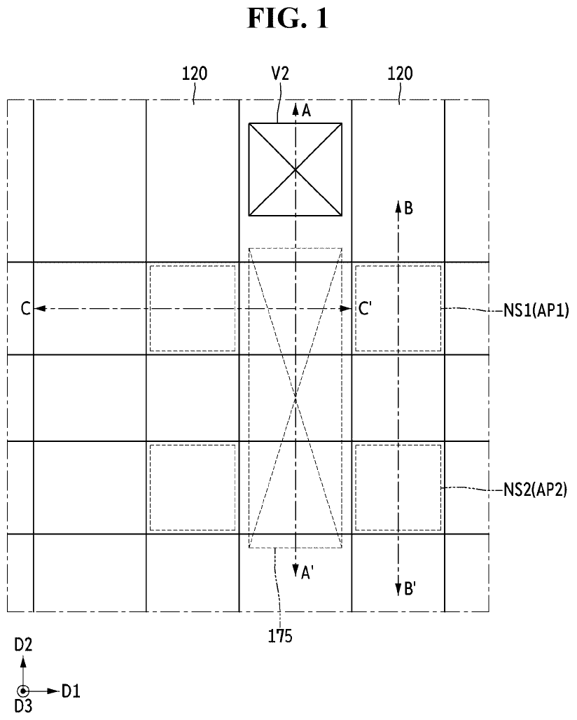

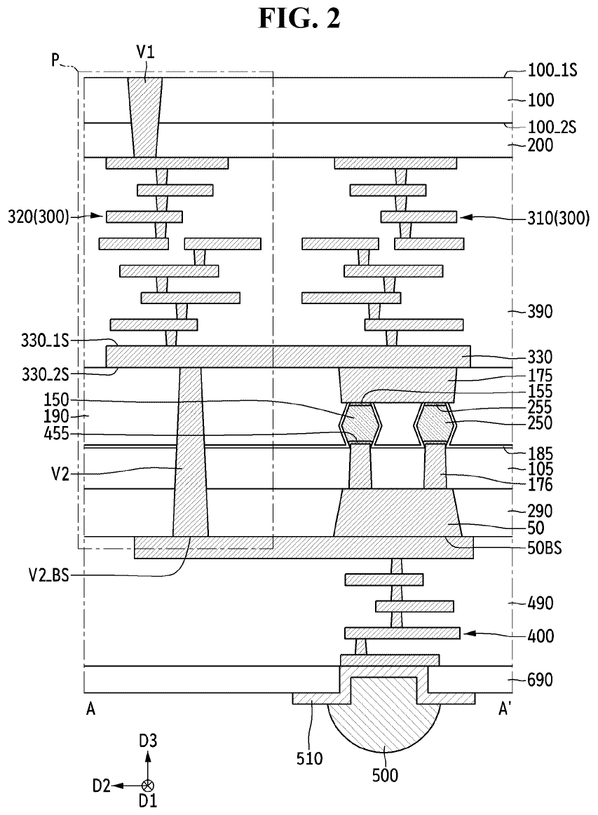

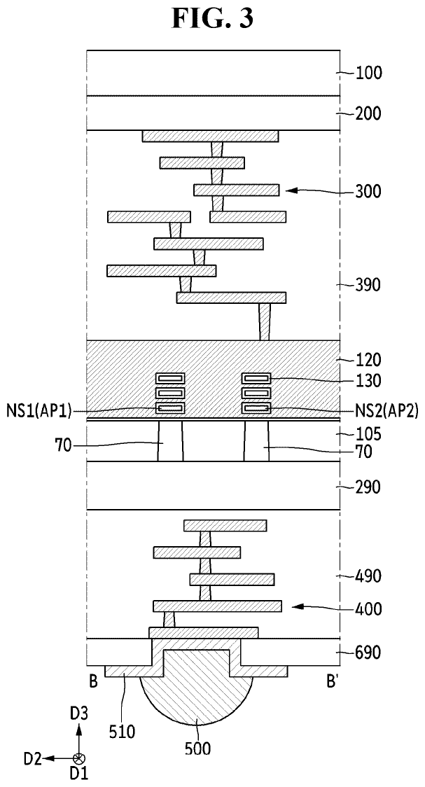

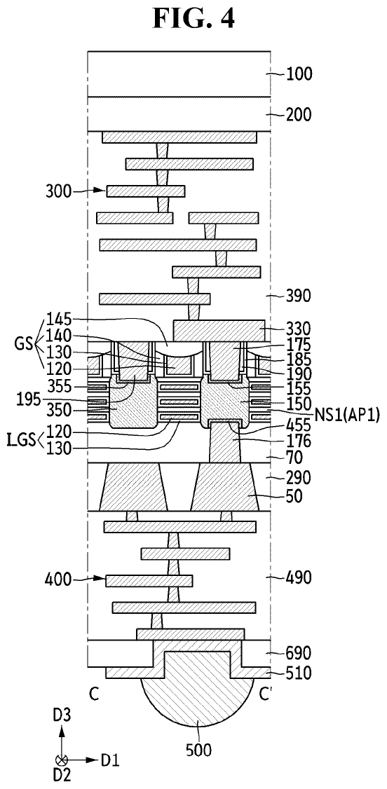

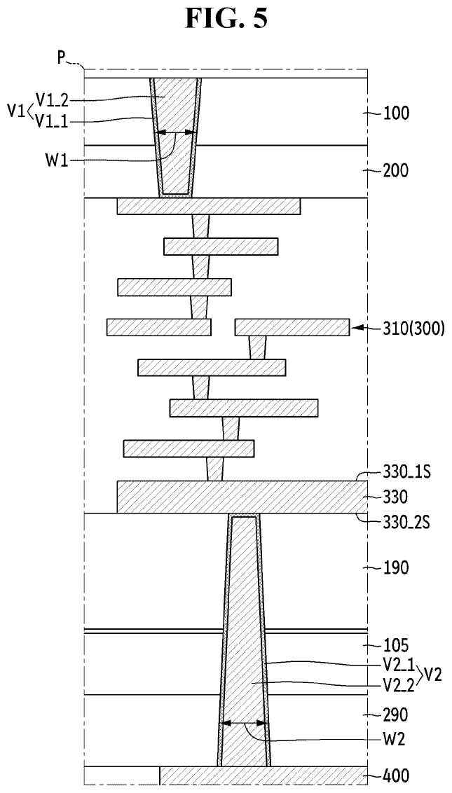

A semiconductor device according to some embodiments of the present disclosure will hereinafter be described with reference to FIGS. 1 through 5. FIG. 1 is an example layout diagram for explaining a semiconductor device according to some embodiments of the present disclosure. FIG. 2 is a cross-sectional view taken along A-A′ of FIG. 1. FIG. 3 is a cross-sectional view taken along B-B′ of FIG. 1. FIG. 4 is a cross-sectional view taken along C-C′ of FIG. 1. FIG. 5 is an enlarged cross-sectional view of part P of FIG. 2.

Referring to FIGS. 1 through 5, the semiconductor device according to some embodiments of the present disclosure may include a support substrate 100, a bonding layer 200, a first via V1, a frontside wiring structure 300, a frontside wiring pattern 330, a frontside source/drain contact 175, first, second, and third source/drain patterns 150, 250, and 350, a source/drain etch stop film 185, a plurality of gate electrodes 120, a first active pattern AP1, a second active pattern AP2, a backside interlayer insulating film 290, backside source/drain contacts 176, backside wiring patterns 50, a second via V2, a backside wiring structure 400, and a bump 500.

The support substrate 100 may extend in a first direction D1 and a second direction D2. The support substrate 100 may include a first surface 100 1S and a second surface 100_2S, which are opposite to each other in a third direction D3. The first direction D1 and the second direction D2 may be parallel with the first surface 100_1S and/or the second surface 100_2S. In this specification, the first, second, and third directions D1, D2, and D3 may intersect one another. The first, second, and third directions D1, D2, and D3 may be (substantially) perpendicular to one another.

The support substrate 100 may include bulk silicon or silicon-on-insulator (SOI). In some embodiments, the support substrate 100 may be a silicon (Si) substrate, or may include other materials, such as silicon-germanium (SiGe), SiGe-on-insulator (SGOI), indium antimonide, a lead telluride compound, indium arsenide, indium phosphide, gallium arsenide, and/or gallium antimonide, but the present disclosure is not limited thereto. The support substrate 100 will hereinafter be described as being a substrate containing Si.

The bonding layer 200 may be disposed on the support substrate 100. The bonding layer 200 may be disposed on the second surface 100_2S of the support substrate 100.

The bonding layer 200 may include an insulating material. The bonding layer 200 may include silicon oxide. For example, the bonding layer 200 may include tetraethyl orthosilicate (TEOS), tonen silazene (TOSZ), atomic layer deposition (ALD) oxide, flowable chemical vapor deposition (FCVD) oxide, high density plasma (HDP) oxide, and/or plasma enhanced oxidation (PEO) oxide, but the present disclosure is not limited thereto.

Although not illustrated, the bonding layer 200 may be composed of multiple layers rather than a single layer. For example, the bonding layer 200 may be composed of three layers. In some embodiments, a first layer of the bonding layer 200 may include SiCN, a second layer of the bonding layer 200 may include TEOS, and a third layer of the bonding layer 200 may include SiCN. The second layer of the bonding layer 200 may be disposed between the first and third layers of the bonding layer 200 (in the third direction D3).

The first via V1 may extend into (e.g., penetrate) the support substrate 100. The first via V1 may extend into (e.g., penetrate) the bonding layer 200. The upper surface of the first via V1 may be disposed on the same plane as (may be coplanar with) the first surface 100_1S of the support substrate 100. The lower surface of the first via V1 may be disposed on the same plane as (may be coplanar with) the lower surface of the bonding layer 200.

The first via V1 may include a first barrier film V1_1 and a first filling film V1_2. The first barrier film V1_1 may extend along the sidewalls and lower surfaces (e.g., bottom surfaces) of holes formed in the support substrate 100 and/or the bonding layer 200. The first filling film V1_2 may be disposed on the first barrier film V1_1 (and may fill the holes).

The first barrier film V1_1 may include a conductive material. The first barrier film V1_1 may include, for example, tantalum (Ta), tantalum nitride (TaN), ruthenium (Ru)-doped TaN, titanium (Ti), titanium nitride (TiN), titanium silicon nitride (TiSiN), tungsten nitride (WN), tungsten carbonitride (WCN), Ru, cobalt (Co), a ruthenium-cobalt (RuCo) alloy, zirconium (Zr), zirconium nitride (ZrN), vanadium (V), vanadium nitride (VN), niobium (Nb), niobium nitride (NbN), platinum (Pt), iridium (Ir), rhodium (Rh), and/or a two-dimensional (2D) material. The first barrier film V1_1 is illustrated as being a single film, but the present disclosure is not limited thereto. For example, contrary to what is illustrated, the first barrier film V1_1 may include multiple conductive films.

The first filling film V1_2 may include a conductive material. The first filling film V1_2 may include, for example, aluminum (Al), copper (Cu), tungsten (W), Co, Ru, silver (Ag), gold (Au), manganese (M n), molybdenum (Mo), Rh, Ir, RuAl, NiAl, NbB₂, MoB₂, TaB₂, V₂AlC, and/or CrAlC.

A width W1 of the first via V1 (in the first direction D1 and/or the second direction D2) may decrease away from the first surface 100_1S of the support substrate 100. The width W1 of the first via V1 may decrease toward the lower surface of the bonding layer 200. The width W1 of the first via V1 may decrease closer to the frontside wiring structure 300.

The frontside wiring structure 300 may be disposed on (the lower surface of) the bonding layer 200. The frontside wiring structure 300 may be disposed within the frontside wiring insulating film 390. The number of layers and the arrangement of the frontside wiring structure 300 described herein and in the drawings are merely examples, and the scopes of the embodiments are not particularly limited thereto.

The frontside wiring structure 300 may include a first frontside wiring structure 310 and a second frontside wiring structure 320.

The first frontside wiring structure 310 may be spaced apart from the second frontside wiring structure 320 in the second direction D2.

For convenience, the first and second frontside wiring structures 310 and 320 are illustrated as not being connected in the second direction D2, but multiple wiring lines may be disposed between the first and second frontside wiring structures 310 and 320. The first and second frontside wiring structures 310 and 320 may be (electrically) connected to each other through the multiple wiring lines.

The second frontside wiring structure 320 may be (electrically) connected to the first via V1. The first via V1 may extend into (e.g., penetrate) the support substrate 100 and the bonding layer 200 to contact the second frontside wiring structure 320. The first via V1 may overlap with the second frontside wiring structure 320 in the third direction D3. The first via V1 may not overlap with the first frontside wiring structure 310 in the third direction D3. For example, the first via V1 may be spaced apart from the first frontside wiring structure 310 in the second direction D2.

The frontside wiring structure 300 may include a conductive material, such as Al, Cu, W, Mo, Co, Ru, or an alloy thereof, but the present disclosure is not limited thereto.

The frontside wiring insulating film 390 may include an insulating material. The frontside wiring insulating film 390 may include, for example, silicon oxide, silicon oxynitride, and/or a low-k dielectric material with a lower dielectric constant than silicon oxide, but the present disclosure is not limited thereto.

The frontside wiring pattern 330 may be disposed on the frontside wiring structure 300. The frontside wiring pattern 330 may be disposed on the first and second frontside wiring structures 310 and 320. The frontside wiring pattern 330 may be (electrically) connected to the first and second frontside wiring structures 310 and 320. The frontside wiring pattern 330 may extend in the second direction D2.

The frontside wiring pattern 330 may include a first surface 330_1S and a second surface 330_2S, which are opposite to each other in the third direction D3. The frontside wiring structure 300 may be disposed on the first surface 330_1S of the frontside wiring pattern 330.

For example, the frontside wiring structure 300 may be disposed between the first surface 330_1S of the frontside wiring pattern 330 and the bonding layer 200 (in the third direction D3).

The frontside wiring pattern 330 may include a conductive material, such as Al, Cu, W, Mo, Co, Ru, or an alloy thereof, but the present disclosure is not limited thereto.

The frontside source/drain contact 175 may be disposed on the second surface 300_2S of the frontside wiring pattern 330. The frontside source/drain contact 175 may be electrically connected to the first and second source/drain patterns 150 and 250.

A first contact silicide film 155 may be disposed between the frontside source/drain contact 175 and the first source/drain pattern 150. The frontside source/drain contact 175 may be (electrically) connected to the first contact silicide film 155. A second contact silicide film 255 may be disposed between the frontside source/drain contact 175 and the second source/drain pattern 250. The frontside source/drain contact 175 may be (electrically) connected to the second contact silicide film 255.

The first and second source/drain patterns 150 and 250 may be disposed on the frontside source/drain contact 175. The third source/drain pattern 350 may be spaced apart from the first source/drain pattern 150 in the first direction D1.

The first, second, and third source/drain patterns 150, 250, and 350 and the frontside source/drain contact 175 may be disposed within a frontside interlayer insulating film 190. The frontside interlayer insulating film 190 may be on (e.g., may cover or overlap) the first, second, and third source/drain patterns 150, 250, and 350 and the frontside source/drain contact 175.

A source/drain contact 195 may be disposed on the third source/drain pattern 350.

A third contact silicide film 355 may be disposed between the source/drain contact 195 and the third source/drain pattern 350. The source/drain contact 195 may be connected to the third contact silicide film 355.

The frontside source/drain contact 175 and the source/drain contact 195 may include, for example, a metal, a conductive metal nitride, a conductive metal carbide, a conductive metal oxide, a conductive metal carbonitride, and/or a 2D material. The first, second, and third contact silicide films 155, 255, and 355 may include, for example, a metal silicide material.

The first, second, and third source/drain patterns 150, 250, and 350 may be disposed between adjacent gate electrodes 120 in the first direction D1. The first, second, and third source/drain patterns 150, 250, and 350 may be disposed on the side surfaces of the gate electrodes 120. The gate electrodes 120 will be described later.

The first and third source/drain patterns 150 and 350 may be in contact with the first sheet patterns NS1, which will be described later. The second source/drain pattern 250 may be in contact with the second sheet patterns NS2, which will be described later.

The first and third source/drain patterns 150 and 350 may be included in the source/drain of a transistor that uses the first sheet patterns NS1 as a channel region. The second source/drain pattern 250 may be included in the source/drain of a transistor that uses the second sheet pattern NS2 as a channel region.

The first, second, and third source/drain patterns 150, 250, and 350 may include, for example, an elemental semiconductor material such as Si or germanium (Ge). The first, second, and third source/drain patterns 150, 250, and 350 may include, for example, a binary or ternary compound containing at least two or more elements selected from carbon (C), Si, Ge, and tin (Sn), or a compound obtained by doping the binary or ternary compound with a Group IV element. The first, second, and third source/drain patterns 150, 250, and 350 may each include an epitaxial film formed of a semiconductor material. The first, second, and third source/drain patterns 150, 250, and 350 may include a dopant that is doped into the semiconductor material.

The source/drain etch stop film 185 may extend along the profile of the first, second, and third source/drain patterns 150, 250, and 350. The source/drain etch stop film 185 may be disposed between the first source/drain pattern 150 and the frontside interlayer insulating film 190 and between the second source/drain pattern 250 and the frontside interlayer insulating film 190. Although not illustrated, the source/drain etch stop film 185 may be disposed between the third source/drain pattern 350 and the frontside interlayer insulating film 190.

The source/drain etch stop film 185 may include, for example, silicon nitride (SiN), silicon oxynitride (SiON), silicon oxycarbonitride (SiOCN), silicon boron nitride (SiBN), silicon oxyboron nitride (SiOBN), silicon oxycarbide (SiOC), and/or a combination thereof.

The first and second active patterns AP1 and AP2 may be disposed on an active layer 70. The active layer 70 may be on (an upper surface of) the backside interlayer insulating film 290.

The first and second active patterns AP1 and A P2 may be spaced apart from each other in the second direction D2. The first and second active patterns AP1 and AP2 may be adjacent to each other in the second direction D2.

The first active pattern AP1 is illustrated as being closest to the second active pattern AP2 in the second direction D2, but the present disclosure is not limited thereto. In some embodiments, additional active patterns may be further disposed between the first and second active patterns AP1 and AP2 (in the second direction D2).

In some embodiments, the first active pattern AP1 may be a region where p-type transistors are formed, and the second active pattern AP2 may be a region where n-type transistors are formed. In some embodiments, the first and second active patterns AP1 and AP2 may be regions where p-type transistors are formed. In some embodiments, the first and second active patterns AP1 and AP2 may both be regions where n-type transistors are formed.

The first and second active patterns AP1 and AP2 may be multi-channel active patterns. The first active pattern AP1 may include a plurality of first sheet patterns NS1. The second active pattern AP2 may include a plurality of second sheet patterns NS2. In some embodiments, the first and second active patterns AP1 and AP2 may be active patterns that include nanosheets and nanowires.

A plurality of first sheet patterns NS1 may be disposed on the active layer 70. The first sheet patterns NS1 may be spaced apart from the backside interlayer insulating film 290 (by the active layer 70) in the third direction D3. Each of the first sheet patterns NS1 may include an upper surface and a lower surface that are opposite to each other in the third direction D3. The lower surfaces of the first sheet patterns NS1 may face the backside interlayer insulating film 290 (and the active layer 70). Each of the first sheet patterns NS1 may include a first end and a second end. The first end of each of the first sheet patterns NS1 may be spaced apart from the second end of the corresponding first sheet pattern NS1 in the first direction D1. The first end of each of the first sheet pattern NS1 may be opposite to the second end of the corresponding first sheet pattern NS1 in the first direction D1. The first and second ends of each of the first sheet patterns NS1 may be portions of the corresponding first sheet pattern NS1 that are (electrically) connected to the first and third source/drain patterns 150 and 350, respectively.

A plurality of second sheet patterns NS2 may be disposed on the active layer 70. The second sheet patterns NS2 may be spaced apart from the backside interlayer insulating film 290 (by the active layer 70) in the third direction D3. Each of the second sheet patterns NS2 may include an upper surface and a lower surface that are opposite to each other in the third direction D3. The lower surfaces of the second sheet patterns NS2 may face the backside interlayer insulating film 290 (and the active layer 70). Each of the second sheet patterns NS2 may include a first end and a second end. The first end of each of the second sheet patterns NS2 may be spaced apart from the second end of the corresponding second sheet pattern NS2 in the first direction D1. The first end of each of the second sheet pattern NS2 may be opposite to the second end of the corresponding second sheet pattern NS2 in the first direction D1. The first and second ends of each of the second sheet patterns NS2 may be portions of the corresponding second sheet pattern NS2 that are (electrically) connected to the second source/drain pattern 250.

Three first sheet patterns NS1 and three second sheet patterns NS2 may be disposed in the third direction D3, but the present disclosure is not limited thereto.

The first sheet patterns NS1 and the second sheet patterns NS2 may each include an elemental semiconductor material such as Si or Ge. The first sheet patterns NS1 and the second sheet patterns NS2 may each include a compound semiconductor, for example, a Group IV-IV compound semiconductor and/or a Group III-V compound semiconductor.

The Group IV-IV compound semiconductor may include, for example, a binary or ternary compound containing at least two or more elements selected from C, Si, Ge, and Sn, or a compound obtained by doping the binary or ternary compound with a Group IV element.

The III-V compound semiconductor may include, for example, a binary, ternary, or quaternary compound formed by combining at least one Group III element, such as Al, Ga, or indium (In), with at least one Group V element, such as phosphorus (P), arsenic (As), or antimony (Sb).

The first sheet patterns NS1 may all have the same width (in the first direction D1 and/or in the second direction D2), but the present disclosure is not limited thereto. The width of the first sheet patterns NS1 (in the first direction D1 and/or in the second direction D2) may increase or decrease in proportion to the width, in the second direction D2, of the active layer 70.

The description of the width of the second sheet patterns NS2 may be (substantially) the same as or similar to the description of the width of the first sheet patterns NS1.

A field insulating film 105 may be disposed on the frontside interlayer insulating film 190. The field insulating film 105 may be on the backside interlayer insulating film 290.

The field insulating film 105 may be between the frontside interlayer insulating film 190 and the backside interlayer insulating film 290 in the third direction D3. The field insulating film 105 may extend around (e.g., at least partially surround) the active layer 70 and the backside source/drain contacts 176, which will be described later.

The field insulating film 105 and the backside interlayer insulating film 290 may include, for example, silicon oxide, silicon nitride, silicon oxynitride, and/or a low-k dielectric material. The field insulating film 105 is illustrated as being a single layer, but the present disclosure is not limited thereto.

A plurality of gate structures GS may be disposed on the field insulating film 105 and the active layer 70.

Each of the gate structures GS may extend in the second direction D2. The gate structures GS may be spaced apart in the first direction D1. The gate structures GS may be adjacent to each other in the first direction D1. The gate structures GS may intersect (e.g., overlap in the third direction D3) the active layer 70.

The gate structures GS may extend around (surround) each of the first sheet patterns NS1. The gate structures GS may extend around (surround) each of the second sheet patterns NS2.

The gate structures GS are illustrated as being arranged across the first and second active patterns AP1 and AP2, but the present disclosure is not limited thereto. That is, some of the gate structures GS may be separated into first portions and second portions by a gate separation structure disposed on the field insulating film 105. In this case, the first portions of the gate structures GS may extend around (surround) the first sheet patterns NS1, and the second portions of the gate structures GS may extend around (surround) the second sheet patterns NS2.

In some embodiments, the gate structures GS may contact the active layer 70. For example, the active layer 70 may contact the lower surfaces (e.g., bottom surfaces) of the gate structures GS.

The gate structures GS may include, for example, gate electrodes 120 and a gate insulating film 130.

The gate structures GS may include a plurality of inner gate structures I_GS that are disposed between adjacent first sheet patterns NS1 in the third direction D3, and between the active layer 70 and the first sheet patterns NS1. The inner gate structures I_ GS may be disposed between the upper surface of the active layer 70 and the lower surfaces of the first sheet patterns NS1, and between the upper and lower surfaces of each of the first sheet patterns NS1 that face each other in the third direction D3. The inner gate structures I_ GS may include the gate electrodes 120 and the gate insulating films 130.

The number of inner gate structures I_GS may be the same as the number of first sheet patterns NS1. The inner gate structures I_GS may contact both the upper surfaces and the lower surfaces of the first sheet patterns NS1.

In some embodiments, the inner gate structures I_GS may contact the upper surface of the active layer 70. The inner gate structures I_ GS may contact the first, second, and third source/drain patterns 150, 250, and 350.

Although not illustrated, the inner gate structures I_ GS may be disposed between adjacent second sheet patterns NS2 in the third direction D3, and between the active layer 70 and the second sheet patterns NS2. The description of the inner gate structures I_GS and the second sheet patterns NS2 may be (substantially) the same as or similar to the description of the innter gate structures I_GS and the first sheet patterns NS1.

The gate electrodes 120 may be disposed on the active layer 70. The gate electrodes 120 may intersect (e.g., overlap in the third direction D3) the active layer 70. The gate electrodes 120 may extend around (surround) the first sheet patterns NS1 and the second sheet patterns NS2.

In the cross-sectional view, such as FIG. 4, the upper surfaces (e.g., the uppermost surfaces) of the gate electrodes 120 are illustrated as being concave surfaces, but the present disclosure is not limited thereto. The upper surfaces (e.g., the uppermost surfaces) of the gate electrodes 120 may be flat.

The gate electrodes 120 may include a metal, a conductive metal nitride, a metal silicide, a doped semiconductor material, a conductive metal oxide, and/or a conductive metal oxynitride. The gate electrodes 120 may include, for example, TiN, tantalum carbide (TaC), TaN, TiSIN, tantalum silicon nitride (TaSiN), tantalum titanium nitride (TaTiN), titanium aluminum nitride (TiAlN), tantalum aluminum nitride (TaAlN), WN, Ru, titanium aluminum (TiAl), titanium aluminum carbonitride (TiAlCN), titanium aluminum carbide (TiAlC), titanium carbide (TiC), tantalum carbonitride (TaCN), W, Al, Cu, Co, Ti, Ta, nickel (Ni), Pt, nickel-platinum (NiPt), Nb, NbN, niobium carbide (NbC), Mo, molybdenum nitride (MoN), molybdenum carbide (MoC), tungsten carbide (WC), Rh, palladium (Pd), Ir, osmium (Os), Ag, Au, zinc (Zn), V, and/or a combination thereof. Here, the conductive metal oxide and conductive metal oxynitride may include oxidized forms of the aforementioned materials, but the present disclosure is not limited thereto.

The gate insulating film 130 may extend along the upper surface of the field insulating film 105 and the upper surface of the active layer 70. The gate insulating film 130 may extend around (surround) the first sheet patterns NS1. The gate insulating film 130 may extend around (surround) the second sheet patterns NS2. The gate insulating film 130 may be disposed along the circumferences of the first sheet patterns NS1 and the circumferences of the second sheet patterns NS2. The gate electrodes 120 may be disposed on the gate insulating film 130.

The gate insulating film 130 may be disposed between the gate electrodes 120 and the first sheet patterns NS1 and between the gate electrodes 120 and the second sheet patterns NS2. For example, the gate insulating film 130 may contact the active layer 70. In some embodiments, portions of the gate insulating film 130 included in the inner gate structures I_GS may later contact the first, second, and third source/drain patterns 150, 250, and 350.

The gate insulating film 130 may include silicon oxide, silicon oxynitride, silicon nitride, and/or a high-k dielectric material with a higher dielectric constant than silicon oxide.

The high-k dielectric material may include, for example, boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanate, barium titanate, strontium titanate, yttrium oxide, aluminum oxide, lead scandium tantalum oxide, and/or lead zinc niobate.

The gate insulating film 130 is illustrated as being a single layer, but the present disclosure is not limited thereto. The gate insulating film 130 may include multiple layers. The gate insulating film 130 may also include an interfacial film disposed between the first sheet patterns NS1 and the gate electrodes 120, and between the second sheet patterns NS2 and the gate electrodes 120 and a high-k dielectric insulating film. For example, the interfacial film may not be formed along the profile of the upper surface of the field insulating film 105.

The semiconductor device according to some embodiments of the present disclosure may include a negative capacitance (NC) FET utilizing a negative capacitor. For example, the gate insulating film 130 may include a ferroelectric material film with ferroelectric properties and a paraelectric material film with paraelectric properties.

The ferroelectric material film may have an NC, and the paraelectric material film may have positive capacitance. For example, if two or more capacitors are connected in series, and each of the capacitors has a positive capacitance, the total capacitance of the capacitors may be reduced compared to the capacitance of each of the capacitors. Conversely, if at least one of the capacitors has an NC, the total capacitance of the capacitors may have a positive value and may be greater than the absolute value of the capacitance of each of the capacitors.

When a ferroelectric material film with an NC and a paraelectric material film with a positive capacitance are connected in series, the total capacitance of the ferroelectric and paraelectric material films may increase. Utilizing this capacitance increase, the transistor including the ferroelectric material film can have a subthreshold swing (SS) of 60 mV/decade or less at room temperature.

The ferroelectric material film may have ferroelectric properties. For example, the ferroelectric material film may include hafnium oxide, hafnium zirconium oxide, barium strontium titanium oxide, barium titanium oxide, and/or lead zirconium titanium oxide. Here, the hafnium zirconium oxide may be, for example, a material obtained by doping hafnium oxide with Zr. The hafnium zirconium oxide may be the compound of hafnium (Hf), Zr, and/or oxygen (O).

The ferroelectric material film may further include a dopant. For example, the dopant may include Al, Ti, Nb, lanthanum (La), yttrium (Y) , magnesium (Mg), Si, calcium (Ca), cerium (Ce), dysprosium (Dy), erbium (Er), gadolinium (Gd), Ge, scandium (Sc), strontium (Sr), and/or Sn. The type of the dopant included in the ferroelectric material film may vary depending on the type of the ferroelectric material included in the ferroelectric material film.

When the ferroelectric material film includes hafnium oxide, the dopant included in the ferroelectric material film may include Gd, Si, Zr, Al, and/or Y.

If the dopant is Al, the ferroelectric material film may contain (about) 3 to 8 atomic % (at %) of Al. Here, the proportion of the dopant may be the ratio of Al to the sum of Hf and Al.

If the dopant is Si, the ferroelectric material film may contain (about) 2 to 10 at % of Si. If the dopant is Y, the ferroelectric material film may contain (about) 2 to 10 at % of Y. If the dopant is Gd, the ferroelectric material film may contain (about) 1 to 7 at % of Gd. If the dopant is Zr, the ferroelectric material film may contain (about) 50 to 80 at % of Zr.

The paraelectric material film may have paraelectric properties. For example, the paraelectric material film may include silicon oxide and/or a high-k metal oxide. The high-k metal oxide may include hafnium oxide, zirconium oxide, and/or aluminum oxide, but the present disclosure is not limited thereto.

The ferroelectric material film and the paraelectric material film may include the same material. The ferroelectric material film may have ferroelectric properties, but the paraelectric material film may not have ferroelectric properties. For example, if both the ferroelectric and paraelectric material films include hafnium oxide, the crystal structure of the hafnium oxide in the ferroelectric material film may differ from the crystal structure of the hafnium oxide in the paraelectric material film.

The ferroelectric material film may have a thickness that exhibits ferroelectric properties. For example, the thickness of the ferroelectric material film may be (about) 0.5 to 10 nm, but the present disclosure is not limited thereto. Since the critical thickness for exhibiting ferroelectric properties may vary from one ferroelectric material to another, the thickness of the ferroelectric material film may vary depending on its material.

For example, the gate insulating film 130 may include one ferroelectric material film. In some embodiments, the gate insulating film 130 may include a plurality of ferroelectric material films that are spaced apart from one another. The gate insulating film 130 may have a layered film structure in which a plurality of ferroelectric material films and a plurality of paraelectric material films are alternately stacked.

Gate spacers 140 may be disposed on the sidewalls of the gate electrodes 120. The gate spacers 140 may not be disposed between the active layer 70 and the first sheet patterns NS1, nor between each pair of adjacent first sheet patterns NS1 in the third direction D3.

The gate spacers 140 may include, for example, SiN, SiON, silicon oxide (e.g., SiO₂), SiOCN, SiBN, SiOBN, SiOC, and/or a combination thereof. The gate spacers 140 are illustrated as being single films, but the present disclosure is not limited thereto.

Gate capping patterns 145 may be disposed on the gate electrodes 120. The upper surfaces of the gate capping patterns 145 may lie on the same plane as (may be coplanar with) the upper surface of the frontside interlayer insulating film 190. In some embodiments, contrary to what is illustrated, the gate capping patterns 145 may be disposed between the gate spacers 140.

The gate capping patterns 145 may include, for example, SiN, SiON, silicon carbonitride (SiCN), SiOCN, and/or a combination thereof. The gate capping patterns 145 may include a material with an etch selectivity with respect to the frontside interlayer insulating film 190.

The backside source/drain contacts 176 may be disposed on the first and second source/drain patterns 150 and 250. A fourth contact silicide film 455 may be disposed between the backside source/drain contacts 176 and the first source/drain pattern 150, and between the backside source/drain contacts 176 and the second source/drain pattern 250. The backside source/drain contacts 176 may be (electrically) connected to the first and second source/drain patterns 150 and 250.

The backside source/drain contacts 176 may include, for example, a metal, a conductive metal nitride, a conductive metal carbide, a conductive metal oxide, a conductive metal carbonitride, and/or a 2D material. The fourth contact silicide film 455 may include a metal silicide material.

The backside wiring pattern 50 may be disposed in the backside interlayer insulating film 290. The backside wiring pattern 50 may be disposed on the active layer 70. The backside wiring pattern 50 may be disposed on the backside source/drain contacts 176. A plurality of backside wiring patterns 50 may be spaced apart from each other in the first direction D1. The backside wiring pattern 50 may be electrically connected to the backside source/drain contacts 176.

The backside wiring pattern 50 may include a conductive material, such as Al, Cu, W, Mo, Co, Ru, and/or an alloy thereof, but the present disclosure is not limited thereto.

The backside interlayer insulating film 290 may be disposed on the field insulating film 105. The backside interlayer insulating film 290 may be on (e.g., cover or overlap in the third direction D3) the backside wiring pattern 50. The backside interlayer insulating film 290 may extend around the backside wiring pattern 50.

The backside interlayer insulating film 290 may include, for example, silicon oxide, silicon oxynitride, and/or a low-k dielectric material with a lower dielectric constant than silicon oxide, but the present disclosure is not limited thereto.

The backside wiring structure 400 may be disposed on the backside interlayer insulating film 290. The backside wiring structure 400 may be disposed on the backside wiring pattern 50. The backside wiring structure 400 may be (electrically) connected to the backside wiring pattern 50. The number of layers and the arrangement of the backside wiring structure 400 illustrated in the drawings are merely example embodiments and not particularly limited thereto.

The backside wiring structure 400 may include a conductive material, such as Al, Cu, W, Mo, Co, Ru, and/or an alloy thereof, but the present disclosure is not limited thereto.

The backside wiring structure 400 may be disposed within the backside wiring insulating film 490. The backside wiring insulating film 490 may be on (e.g., cover or overlap) the backside wiring structure 400. The backside wiring insulating film 490 may extend around the backside wiring structure 400.

The backside wiring insulating film 490 may include, for example, silicon oxide, silicon oxynitride, and/or a low-k dielectric material with a lower dielectric constant than silicon oxide, but the present disclosure is not limited thereto.

The second via V2 may be disposed between the frontside wiring pattern 330 and the backside wiring structure 400. The second via V2 may be spaced apart from the backside wiring pattern 50 in the second direction D2. The second via V2 may extend in the third direction D3. The second via V2 may be disposed on the second surface 300 2S of the frontside wiring pattern 330. The second via V2 may be disposed on the backside wiring structure 400.

The second via V2 may not overlap with the first frontside wiring structure 310 in the third direction D3. For example, the second via V2 may be spaced apart from the first frontside wiring structure 310 in the second direction D2. The second via V2 may overlap with the second frontside wiring structure 320 in the third direction D3. The second via V2 may overlap with the backside wiring pattern 50, the backside source/drain contacts 176, the first and second source/drain patterns 150 and 250, and/or the frontside source/drain contact 175 in the second direction D2. The first frontside wiring structure 310 may overlap the backside source/drain contacts 176 (and/or the active layer 70), the first and second source/drain patterns 150 and 250, the frontside source/drain contact 175, and/or the backside wiring pattern 50 in the third direction D3. The second via V2 may be spaced apart from the backside wiring pattern 50, the backside source/drain contacts 176, the first and second source/drain patterns 150 and 250, and/or the frontside source/drain contact 175 in the second direction D2. The first via V1 may be spaced apart from the backside wiring pattern 50, the backside source/drain contacts 176, the first and second source/drain patterns 150 and 250, and/or the frontside source/drain contact 175 in the second direction D2.

The second via V2 may extend into (penetrate) the backside interlayer insulating film 290, the field insulating film 105, and the frontside interlayer insulating film 190. A width W2 of the second via V2 may decrease closer to the frontside wiring pattern 330. The width W2 of the second via V2 may increase closer to the backside wiring structure 400.

Based on the second surface 300_2S of the frontside wiring pattern 330, the level of a lower surface V2_BS of the second via V2 may be the same level as the level of a lower surface 50BS of the backside wiring pattern 50. For example, the lower surface V2_BS may be coplanar with the lower surface 50BS. Herein, the term “level”, “vertical level”, “height”, or the like may refer to a relative location with respect to (e.g., a distance from) a reference element in the third direction D3. For example, a higher level may mean a farther distance from a lowest reference element in a drawing in the third direction D3, and a lower level may mean a closer distance to the lowest reference element in the drawing in the third direction D3.

The second via V2 may include a second barrier film V2_1 and a second filling film V2_2 . The second barrier film V2_1 may extend along the sidewalls and lower surfaces (e.g., bottom surfaces) of holes formed in the backside interlayer insulating film 290, the field insulating film 105, and the frontside interlayer insulating film 190. In FIG. 5, the lower surfaces of the holes may face the frontside wiring pattern 330. The second filling film V2_2 may be disposed on the second barrier film V2_1. The second filling film may at least partially fill the holes in the backside interlayer insulating film 290, the field insulating film 105, and the frontside interlayer insulating film 190.

The second barrier film V2_1 may include a conductive material. The description of the second barrier film V2_1 may be (substantially) the same as (or similar to) the description of the first barrier film V1_1. The second filling film V2_2 may include a conductive material.

The description of the second filling film V2_2 may be (substantially) the same as (or similar to) the description of the first filling film V1_2.

A pad insulating film 690 may be disposed on the backside wiring insulating film 490. The pad insulating film 690 may include an insulating material, such as silicon oxide, silicon oxynitride, or a low-k dielectric material with a lower dielectric constant than silicon oxide, but the present disclosure is not limited thereto.

A bump pad 510 may be disposed in (within) the pad insulating film 690. The bump pad 510 may be disposed on the pad insulating film 690. The bump pad 510 may be (electrically) connected to the backside wiring structure 400. The bump pad 510 may (electrically) connect the bump 500, which will be described later, to the backside wiring structure 400.

The bump pad 510 may include, for example, a metallic material such as Al, Cu, Ni, W, Pt, and/or Au, but the present disclosure is not limited thereto.

The bump 500 may be disposed on the bump pad 510. The bump 500 may be a solder bump that includes a low-melting-point metal, such as Sn or an Sn alloy, but the present disclosure is not limited thereto. The bump 500 may have various shapes, such as a land, ball, pin, or pillar. The bump 500 may include under-bump metallurgy (UBM).

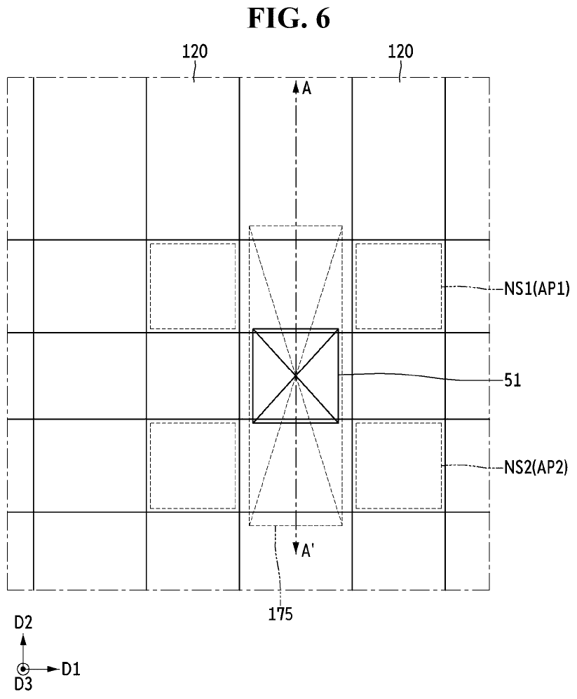

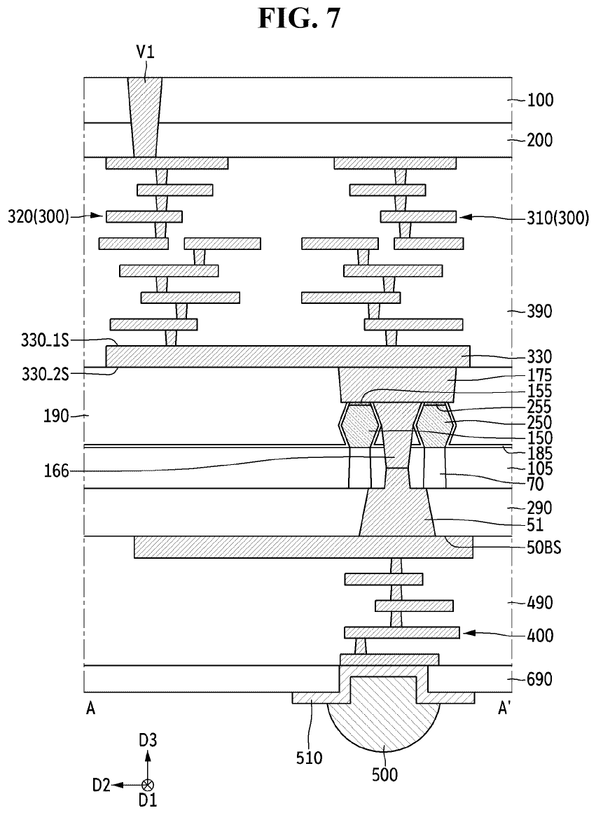

FIG. 6 and FIG. 7 are diagrams for explaining a semiconductor device according to some embodiments of the present disclosure. FIG. 7 is a cross-sectional view taken along line A-A′ of FIG. 6. For convenience, overlapping content with what has been described above with reference to FIGS. 1 through 5 may be briefly explained or omitted.

Referring to FIGS. 6 and 7, the semiconductor device according to some embodiments of the present disclosure may include a support substrate 100, a bonding layer 200, a first via V1, a first frontside wiring structure 310, a second frontside wiring structure 320, a frontside wiring pattern 330, a frontside source/drain contact 175, a first source/drain pattern 150, a second source/drain pattern 250, a connection contact via 166, a backside wiring structure 400, and a bump 500.

The descriptions of the support substrate 100, the bonding layer 200, the first via V1, the first frontside wiring structure 310, the second frontside wiring structure 320, the frontside wiring pattern 330, the backside wiring structure 400, and the bump 500 are substantially the same as the descriptions of their respective counterparts of FIGS. 1 through 5.

The frontside source/drain contact 175 may be disposed on a second surface 300_2S of the frontside wiring pattern 330. The first and second source/drain patterns 150 and 250 may be disposed on the frontside source/drain contact 175.

The active layer 70 may be disposed on the first and second source/drain patterns 150 and 250. The field insulating film 105 may be disposed on the sidewalls of the active layer 70. The field insulating film 105 may cover the active layer 70. The field insulating film 105 may extend around the active layer 70.

The connection contact via 166 may be disposed on the frontside source/drain contact 175. The connection contact via 166 may be disposed between the first and second source/drain patterns 150 and 250 (in the second direction D2). The connection contact via 166 may extend in the third direction D3. The connection contact via 166 and the frontside source/drain contact 175 may form an integral structure without an interface therebetween.

The connection contact via 166 may extend in the third direction D3. The connection contact via 166 may overlap with the first frontside wiring structure 310 in the third direction D3. The connection contact via 166 may not overlap with the second frontside wiring structure 320 in the third direction D3. The connection contact via 166 may penetrate the source/drain etch stop film 185 and the upper surface of the field insulating film 105. The width of the connection contact via 166 may decrease away from the frontside source/drain contact 175 in the third direction D3.

The connection contact via 166 may include, for example, a metal, a conductive metal nitride, a conductive metal carbide, a conductive metal oxide, a conductive metal carbonitride, and/or a 2D material.

The backside wiring pattern 51 may be disposed on the backside wiring structure 400. The backside wiring pattern 51 may extend in the third direction D3 and may be (electrically) connected to the connection contact via 166.

The backside wiring pattern 51 may penetrate the backside interlayer insulating film 290. A portion of the backside wiring pattern 51 may be disposed in (within) the backside interlayer insulating film 290. The width of the backside wiring pattern 51 may decrease away from the backside wiring structure 400 in the third direction D3.

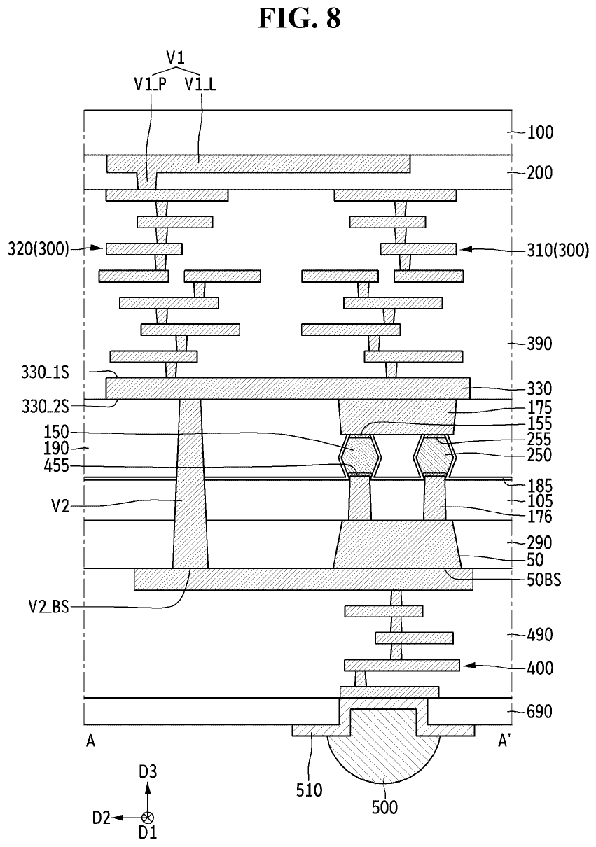

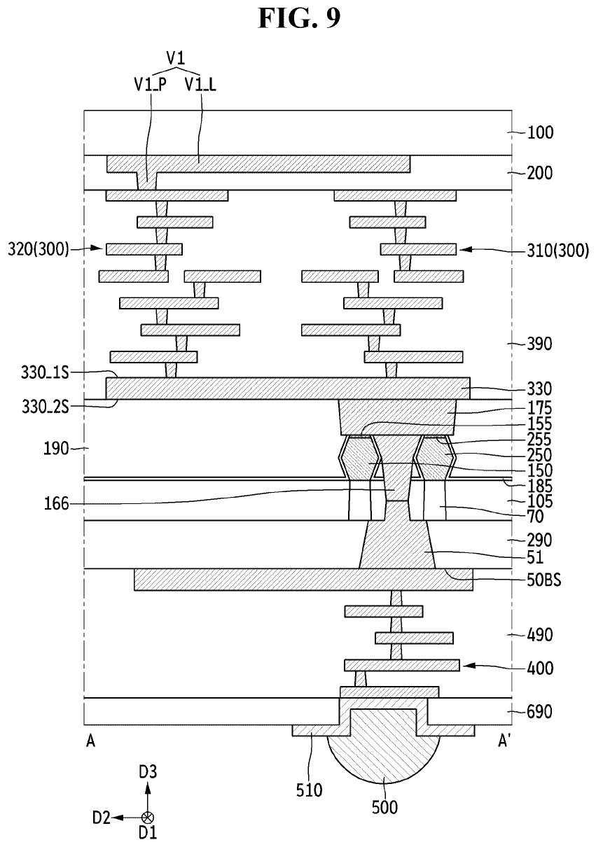

FIGS. 8 and 9 are diagrams for explaining semiconductor devices according to some embodiments of the present disclosure. For convenience, overlapping content with what has been described above with reference to FIGS. 1 through 5 may be briefly explained or omitted.

The description of the embodiment of FIG. 8 may be (substantially) the same as (or similar to) the description of the embodiment of FIGS. 1 through 5, except for the description of a first via V1. The description of the embodiment of FIG. 9 may be (substantially) the same as (or similar to) the description of the embodiment of FIGS. 6 and 7, except for the description of a first via V1.

Referring to FIGS. 8 and 9, the first via V1 may be disposed in (within) a bonding layer 200. The first via V1 may include a first line pattern V1_L and a first protrusion pattern V1_P.

The first line pattern V1_L may extend in the second direction D2. In FIG. 8, the first line pattern V1_L may overlap with a second frontside wiring structure 320 in the third direction D3, but the present disclosure is not limited thereto. In some embodiments, the first line pattern V1_L may not overlap with the second frontside wiring structure 320 in the third direction D3.

The upper surface of the first line pattern V1_L may be disposed on the same plane as the upper surface of the bonding layer 200. The upper surface of the first line pattern V1_L may be coplanar with the upper surface of the bonding layer 200. The upper surface of the first line pattern V1_L may be exposed from the upper surface of the bonding layer 200. The side surfaces of the first line pattern V1_L may be surrounded by the bonding layer 200. The bonding layer 200 may be on the side surfaces of the first line pattern V1_L.

The first protrusion pattern V1__P may protrude from the first line pattern V1_L. The first protrusion pattern V1_P may extend in the third direction D3 from the first line pattern V1_L.

The first protrusion pattern V1_P may be (electrically) connected to the second frontside wiring structure 320. The first protrusion pattern V1_P may overlap with the second frontside wiring structure 320 in the third direction D3. The first protrusion pattern V1_P may not overlap with a first frontside wiring structure 310 in the third direction D3.

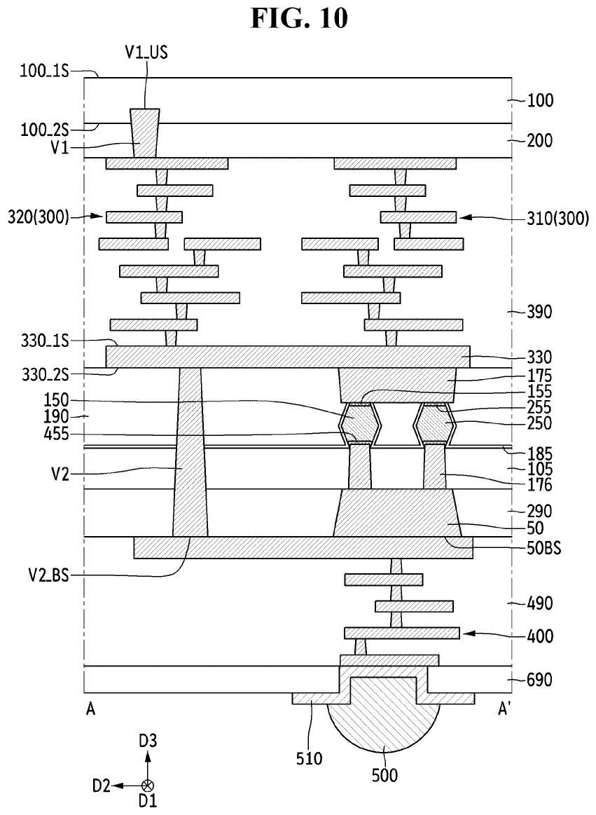

FIG. 10 is a diagram for explaining a semiconductor device according to some embodiments of the present disclosure. For convenience, overlapping content with what has been described above with reference to FIGS. 1 through 5 may be briefly explained or omitted.

The description of the embodiment of FIG. 10 may be (substantially) the same as (or similar to) the description of the embodiment of FIGS. 1 through 5, except for the description of a first via V1.

Referring to FIG. 10, the first via V1 may extend into (e.g., penetrate) a bonding layer 200. A portion of the first via V1 may be disposed in (within) the bonding layer 200, and another portion of the first via V1 may be disposed in (within) a support substrate 100.

An upper surface V1_US of the first via V1 may be higher than a second surface (e.g., a lower surface) 100_2S of the support substrate 100. The upper surface V1_US of the first via V1 may be lower than a first surface (e.g., an upper surface) 100_1S of the support substrate 100.

Typically, a semiconductor device generates heat during operation. This heat may escape through the support substrate 100. However, if the heat escapes through a frontside source/drain contact 175 and a first frontside wiring structure 310 into the support substrate 100, it may affect the metals and films included in the semiconductor device.

However, the semiconductor device according to some embodiments of the present disclosure may include the first via V1, the second frontside wiring structure 320, and/or a second via V2. The first via V1 may penetrate the support substrate 100 and/or the bonding layer 200. The second via V2 may be spaced apart from the frontside source/drain contact 175 and first and second source/drain patterns 150 and 250 in the second direction D2. The second frontside wiring structure 320 may be spaced apart from the first frontside wiring structure 310 in the second direction D2. Heat generated during operation may escape through the first via V1. Heat may escape through the second frontside wiring structure 320. Heat may escape through the second via V2. Since the semiconductor device according to some embodiments of the present disclosure includes the first via V1, the second frontside wiring structure 320, and/or the second via V2, a thermal dissipation path may be formed (spaced apart from the source of the heat (the operating portion of the semiconductor device)).

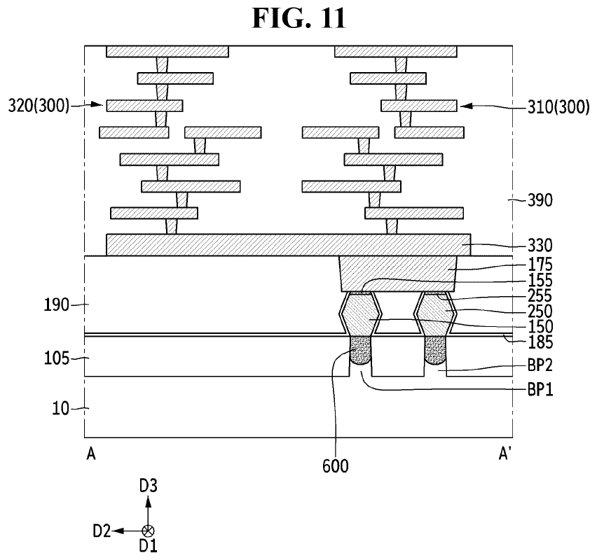

FIGS. 11 through 16 are diagrams for explaining a method of manufacturing a semiconductor device according to some embodiments of the present disclosure. FIGS. 11 through 16 are diagrams for explaining a method of manufacturing the semiconductor device of FIG. 2. For convenience, overlapping content with what has been described above with reference to FIGS. 1 through 5 may be briefly explained or omitted.

Referring to FIG. 11, a first source/drain pattern 150 and a second source/drain pattern 250 may be formed on a first lower pattern BP1 and a second lower pattern BP2, respectively, on a substrate 10. A frontside source/drain contact 175 may be formed on the first and second source/drain patterns 150 and 250. A frontside wiring pattern 330 may be formed on the frontside source/drain contact 175 and may extend in the second direction D2. A frontside wiring structure 300 may be formed on the frontside wiring pattern 330.

The first and second lower patterns BP1 and BP2 may protrude in the third direction D3 from the upper surface of a substrate 10. Alignment patterns 600 may be formed within the first and second lower patterns BP1 and BP2. The first and second source/drain patterns 150 and 250 may be formed on the alignment patterns 600.

The side surfaces of the first and second lower patterns BP1 and BP2 may be covered by a field insulating film 105. The field insulating film 105 may be on the side surfaces of the first and second lower patterns BP1 and BP2. The field insulating film 105 may extend around the first and second lower patterns BP1 and BP2. A frontside interlayer insulating film 190 may be on (e.g., may cover or may extend around) the first source/drain pattern 150, the second source/drain pattern 250, and the frontside source/drain contact 175. A frontside wiring insulating film 390 may be on (e.g., may cover or may extend around) the frontside wiring pattern 330 and the frontside wiring structure 300.

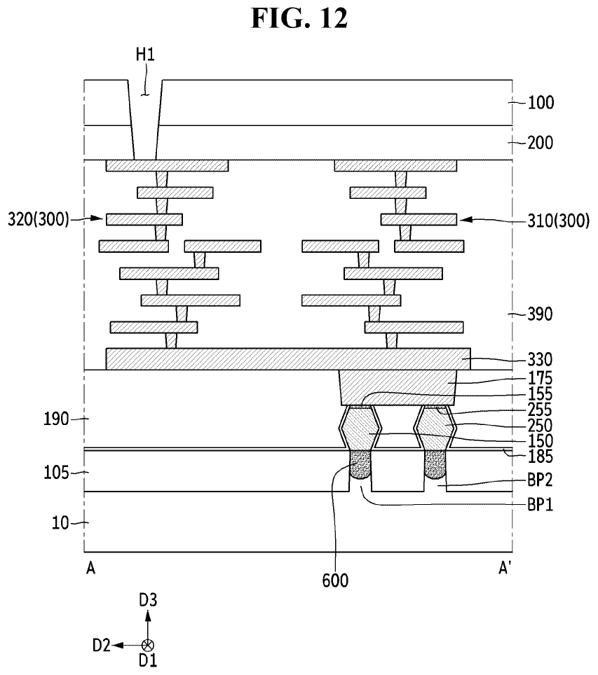

Referring to FIG. 12, a bonding layer 200 and a support substrate 100 may be formed on the frontside wiring insulating film 390, and a first hole H1 may be formed in the bonding layer 200 and/or the support substrate 100.

The bonding layer 200 and the support substrate 100 may be sequentially formed on the frontside wiring insulating film 390. The first hole H1 may extend into (penetrate) the bonding layer 200 and the support substrate 100. A portion of the frontside wiring insulating film 390 may be exposed through the first hole H. The first hole H1 may not overlap with a first frontside wiring structure 310 in the third direction D3. The first hole H1 may overlap with a second frontside wiring structure 320 in the third direction D3.

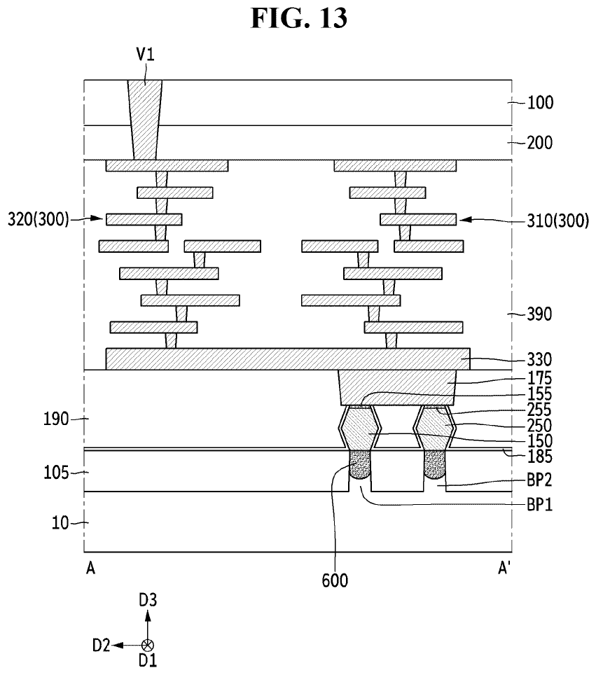

Referring to FIG. 13, a first via V1 may be formed in (within) the bonding layer 200 and the support substrate 100.

The first via V1 may be formed by (at least partially) filling a conductive material into the first hole H 1. The first via V1 is illustrated as being a single layer, but the present disclosure is not limited thereto. The first via V1 may include a first barrier film V1_1 and a first filling film V1_2, as illustrated in FIG. 5.

The first via V1 may be (electrically) connected to the second frontside wiring structure 320. The first via V1 may not overlap with the first frontside wiring structure 310 in the third direction D3. The first via V1 may overlap with the second frontside wiring structure 320 in the third direction D3.

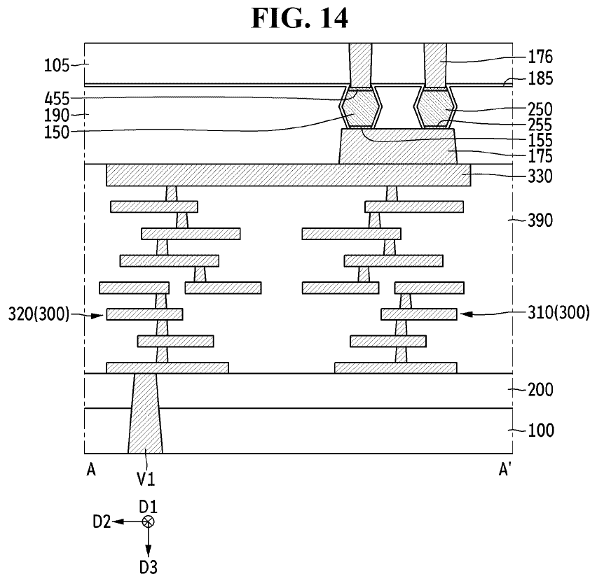

Referring to FIG. 14, the result from FIG. 13 may be flipped, and a backside source/drain contact 176 is formed on the first and second source/drain patterns 150 and 250.

The result from FIG. 13 may be flipped, and the substrate 10 may be removed. Thereafter, the first lower pattern BP1, the second lower pattern BP2, and the alignment pattern 600 may be removed. A conductive material may be filled in the spaces where the first lower pattern BP1, the second lower pattern BP2, and the alignment pattern 600 are removed to form backside source/drain contacts 176. The side surfaces of the backside source/drain contacts 176 may be covered by the field insulating film 105. The field insulating film 105 may extend around the backside source/drain contacts 176.

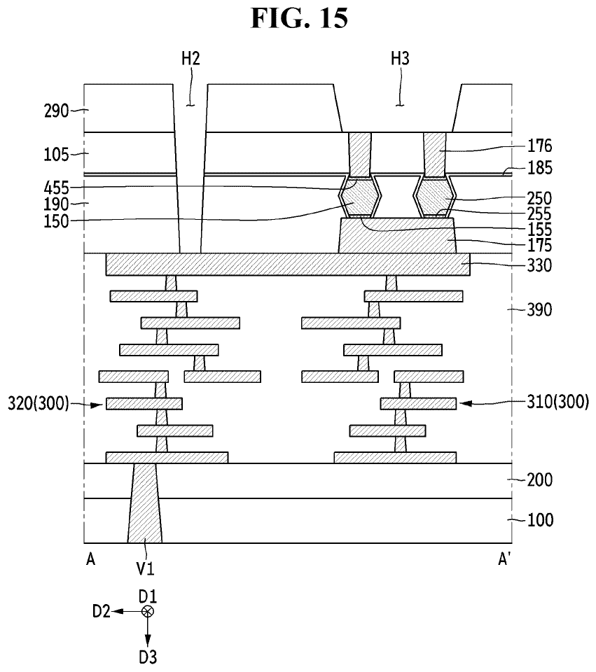

Referring to FIG. 15, a backside interlayer insulating film 290 may be formed, and a second hole H2 and a third hole H3 may be formed in the backside interlayer insulating film 290.

The backside interlayer insulating film 290 may be formed on the field insulating film 105. The second hole H2 may be formed to extend into (penetrate) the backside interlayer insulating film 290, the field insulating film 105, and/or the frontside interlayer insulating film 190. The third hole H3 may be formed in (within) the backside interlayer insulating film 290.

The second hole H2 may expose the frontside wiring pattern 330. The third hole H3 may expose the backside source/drain contacts 176.

The second hole H2 may overlap with the second frontside wiring structure 320 in the third direction D3, but may not overlap with the first frontside wiring structure 310 in the third direction D3.

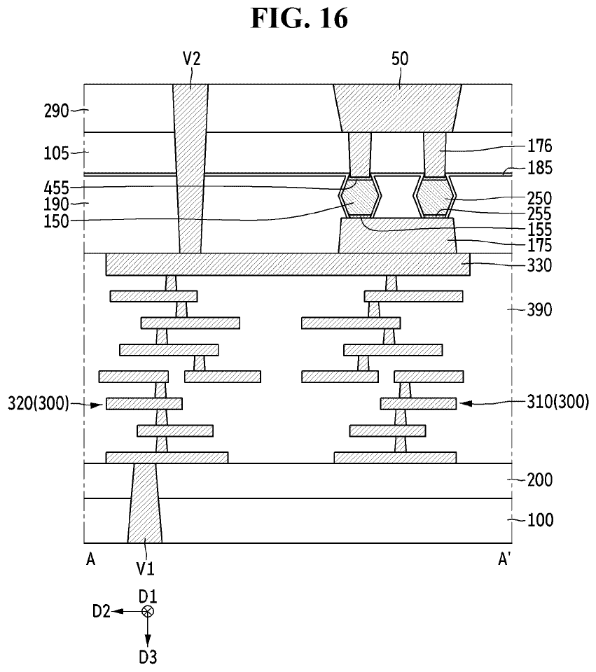

Referring to FIG. 16, a second via V2 may be formed on the frontside wiring pattern 330, and a backside wiring pattern 50 may be formed on the backside source/drain contacts 176.

The second via V2 may be formed by (at least partially) filling a conductive material into the second hole H2. In FIG. 16, the second via V2 is illustrated as being a single layer, but the present disclosure is not limited thereto. The second via V2 may include a second barrier film V2_1 and a second filling film V2_2, as illustrated in FIG. 5.

The second via V2 may be (electrically) connected to the frontside wiring pattern 330. The second via V2 may overlap with the second frontside wiring structure 320 in the third direction D3. The second via V2 may not overlap with the first frontside wiring structure 310 in the third direction D3.

The second via V2 may penetrate the backside interlayer insulating film 290, the field insulating film 105, and the frontside interlayer insulating film 190. The second via V2 may overlap with the backside wiring pattern 50, the backside source/drain contacts 176, the first and second source/drain patterns 150 and 250, and the frontside source/drain contact 175 in the second direction D2.

The third hole H3 may be (at least partially) filled with a conductive material to form the backside wiring pattern 50. The backside wiring pattern 50 may be (electrically) connected to the backside source/drain contacts 176.

Thereafter, referring to FIG. 2, a backside wiring structure 400 may be formed on the second via V2 and the backside wiring pattern 50. A bump pad 510 and a bump 500 may be formed on the backside wiring structure 400.

Although embodiments of the present disclosure have been described with reference to the accompanying drawings, the present disclosure is not limited to the above embodiments but may be implemented in various different forms. A person skilled in the art may appreciate that the present disclosure may be practiced in other concrete forms without changing the technical scope or essential characteristics of the present disclosure. Therefore, it should be appreciated that the embodiments as described above is not restrictive but illustrative in all respects.

1. A semiconductor device comprising:
a support substrate;
a bonding layer on the support substrate;
a first frontside wiring structure on the bonding layer;
a second frontside wiring structure on the bonding layer, wherein the second frontside wiring structure is spaced apart from the first frontside wiring structure in a first direction that is parallel with an upper surface of the support substrate;
a frontside wiring pattern on the first frontside wiring structure and the second frontside wiring structure, wherein the frontside wiring pattern extends in the first direction;
a frontside source/drain contact on the frontside wiring pattern;
a source/drain pattern on the frontside source/drain contact;
a backside wiring pattern on the source/drain pattern;
a backside wiring structure on the backside wiring pattern; and
a first via extending into the bonding layer, wherein the first via is in contact with the second frontside wiring structure,
wherein the first via overlaps the second frontside wiring structure in a second direction that is perpendicular to the upper surface of the support substrate.

2. The semiconductor device of claim 1, further comprising:
a backside source/drain contact between the backside wiring pattern and the source/drain pattern; and
a second via that is spaced apart from the backside wiring pattern in the first direction and between the frontside wiring pattern and the backside wiring structure.

3. The semiconductor device of claim 2, wherein the second via overlaps the second frontside wiring structure in the second direction, and
wherein the second via is spaced apart from the backside wiring pattern, the backside source/drain contact, and the source/drain pattern in the first direction.

4. The semiconductor device of claim 2, wherein the backside wiring pattern, the backside source/drain contact, and the source/drain pattern overlap the second via in the first direction.

5. The semiconductor device of claim 2, wherein a lower surface of the second via is coplanar with a lower surface of the backside wiring pattern.

6. The semiconductor device of claim 2, wherein the frontside wiring pattern comprises a first surface and a second surface that is opposite to the first surface in the second direction,
wherein the first frontside wiring structure and the second frontside wiring structure are on the first surface of the frontside wiring pattern,
wherein the second surface of the frontside wiring pattern faces the backside wiring structure,
wherein a width of the first via in the first direction decreases as the first via extends toward the frontside wiring pattern, and
wherein a width of the second via in the first direction decreases as the second via extends toward the frontside wiring pattern.

7. The semiconductor device of claim 2, wherein the first via extends in the second direction and extends into the support substrate.

8. The semiconductor device of claim 2, wherein the first via comprises a first line pattern in the bonding layer and a first protrusion pattern that protrudes from the first line pattern in the second direction,
wherein the first line pattern is in contact with the support substrate, and
wherein the first protrusion pattern is in contact with the second frontside wiring structure.

9. The semiconductor device of claim 1, further comprising:
a connection contact via between the backside wiring pattern and the frontside source/drain contact,
wherein the connection contact via connects the backside wiring pattern and the frontside source/drain contact.

10. The semiconductor device of claim 9, wherein the first via extends in the second direction and extends into the support substrate.

11. The semiconductor device of claim 9, wherein the first via comprises a first line pattern in the bonding layer and a first protrusion pattern that protrudes from the first line pattern in the second direction,
wherein the first line pattern is in contact with the support substrate, and
wherein the first protrusion pattern is in contact with the second frontside wiring structure.

12. A semiconductor device comprising:
a support substrate;
a bonding layer on the support substrate;
a frontside wiring pattern on the bonding layer, wherein the frontside wiring pattern extends in a first direction that is parallel with an upper surface of the support substrate;
a frontside wiring structure between the frontside wiring pattern and the bonding layer in a second direction that is perpendicular to the upper surface of the support substrate, wherein the frontside wiring structure is in contact with the frontside wiring pattern;
a first via extends into the bonding layer and the support substrate, wherein the first via is in contact with the frontside wiring structure;
a frontside source/drain contact on the frontside wiring pattern;
a source/drain pattern on the frontside source/drain contact;
a backside wiring pattern on the source/drain pattern, wherein the backside wiring pattern is spaced apart from the frontside wiring pattern in the second direction;
a backside wiring structure on the backside wiring pattern; and
a second via that is spaced apart from the backside wiring pattern in the first direction,
wherein the second via extends in the second direction and connects the backside wiring structure and the frontside wiring pattern, and
wherein a lower surface of the second via is coplanar with a lower surface of the backside wiring pattern.

13. The semiconductor device of claim 12, wherein the frontside wiring structure comprises a first frontside wiring structure and a second frontside wiring structure that is spaced apart from the first frontside wiring structure in the first direction,
wherein the frontside source/drain contact overlaps the first frontside wiring structure in the second direction,
wherein the second via overlaps the second frontside wiring structure in the second direction, and
wherein the second via is spaced apart from the frontside source/drain contact in the first direction.

14. The semiconductor device of claim 12, wherein the backside wiring pattern and the source/drain pattern overlap the second via in the first direction.

15. The semiconductor device of claim 12, wherein the frontside wiring structure comprises a first frontside wiring structure and a second frontside wiring structure that is spaced apart from the first frontside wiring structure in the first direction, and
wherein the second via is free of overlap with the first frontside wiring structure in the second direction and overlaps the second frontside wiring structure in the second direction.

16. The semiconductor device of claim 15, wherein the first via is free of overlap with the first frontside wiring structure in the second direction and overlaps the second frontside wiring structure in the second direction.

17. The semiconductor device of claim 12, wherein the first via comprises a first line pattern in the bonding layer and a first protrusion pattern that protrudes from the first line pattern in the second direction,
wherein the first line pattern is in contact with the support substrate, and
wherein the first protrusion pattern is in contact with the frontside wiring structure.

18. The semiconductor device of claim 12, wherein respective widths of the first via and the second via in the first direction decrease as the first via and the second via get closer to the frontside wiring pattern in the second direction.

19. A semiconductor device comprising:
a support substrate;
a bonding layer on the support substrate;
a first via extending into the support substrate and the bonding layer;
a first frontside wiring structure on the bonding layer;
a second frontside wiring structure on the first via, wherein the second frontside wiring structure is spaced apart from the first frontside wiring structure in a first direction that is parallel with an upper surface of the support substrate and in contact with the first via;
a frontside wiring pattern on the first frontside wiring structure and the second frontside wiring structure, wherein the frontside wiring pattern extends in the first direction;
a frontside source/drain contact on the frontside wiring pattern;
a source/drain pattern on the frontside source/drain contact;
a backside wiring pattern on the source/drain pattern;
a backside wiring structure on the backside wiring pattern, wherein the backside wiring structure is in contact with the backside wiring pattern;
a bump on the backside wiring structure; and
a second via that is spaced apart from the backside wiring pattern in the first direction, wherein the second via extends in a second direction that is perpendicular to the upper surface of the support substrate between the frontside wiring pattern and the backside wiring structure,
wherein the first via and the second via are free of overlap with the first frontside wiring structure in the second direction and overlap the second frontside wiring structure in the second direction, and
wherein a lower surface of the second via is coplanar with a lower surface of the backside wiring pattern.

20. The semiconductor device of claim 19, wherein respective widths of the first via and the second via in the first direction decrease as the first via and the second via get closer to the frontside wiring pattern in the second direction
